(19) United States
(12) Patent Application Publication
(10) Pub. No.: US 2025/0355368 A1
(43) Pub. Date: Nov. 20, 2025

(54) METROLOGY TO REDUCE OVERLAY ERROR

(71) Applicant: Onto Innovation Inc., Wilmington, MA (US)

(72) Inventors: Keith F. Best, Andover, MA (US); Woo Young Han, Frisco, TX (US); John Chang, Taichung (TW)

(21) Appl. No.: 18/664,068

(22) Filed: May 14, 2024

(51) Int. Cl. G03F 7/00

(52) U.S. Cl. CPC G03F 7/70633; G03F 7/70625; G03F 7/706839

(57) ABSTRACT

Various examples herein describe an apparatus and related method to track and correct alignment errors of features used on a substrate. For example, in various embodiments, the disclosed subject-matter is a method for measuring x-coordinates and y-coordinates of a number of features (such as vias) on a layer on the substrate for each of the layers formed on the substrate that are to underlie a subsequently formed layer; compare the x-coordinates and the y-coordinates on the layer to respective locations of a production file used to determine a planned location of the features for each of the respective layers; prepare offset data based on the comparison for each of the respective layers; and enter the offset data into a lithographic tool database to minimize or correct the alignment errors for each of the respective layers. Other systems, apparatuses, and methods are also disclosed.

### TECHNOLOGY FIELD

The disclosed subject-matter is related generally to the field of aligning lithographic equipment used in fabrication or manufacturing facilities. More specifically, in various embodiments, the disclosed subject-matter relates to techniques to reduce alignment errors.

### BACKGROUND

Manufacturing production lines for advanced packaging including Advanced Integrated Circuit Substrates (AICSs) use lithographic equipment (also known as lithographic tools and includes, for example, photolithographic steppers (steppers) or scanners, and direct-write lithography (maskless lithography)). Typically, the advanced packaging process uses laser drilling to form via holes in, for example, Ajinomoto Build-up Film (ABF) layers used to interconnect various redistribution layers (RDLs) within the advanced packaging substrate. Critical dimension (CD) and X, Y location of these via holes are used to ensure high-yielding packages through numerous layers. For example, an advanced packaging substrate may have 20 or more process layers (e.g., 10 process layers on a frontside of the substrate and 10 layers on a backside of the substrate).

### SUMMARY

This document describes, among other things, various types of techniques, methods, and mechanisms to track and correct alignment errors of vias used to form integrated circuits on a substrate. For example, in various embodiments, the disclosed subject-matter includes a method to perform measurements and track dx- and dy-displacement errors of vias formed through the substrate, prepare alignment data offsets to correct displacement errors, and enter the alignment data into a lithographic tool database.

In various embodiments, the disclosed subject-matter includes a method for producing alignment data for a lithographic tool for each of a plurality of layers formed on a substrate that are to underlie a subsequently formed layer. The method includes receiving measurement data for a substrate for each of a plurality of vias within a layer as the plurality of layers are being formed on a substrate. The measurement data including at least an x-coordinate and a y-coordinate of at least a portion of the plurality of vias on a layer of the substrate. The method also includes comparing the x-coordinate and the y-coordinate of at least the portion of the plurality of vias on a current layer of the substrate to respective locations of a production file used to determine a planned location of the plurality of vias on the current layer; preparing offset data based on the comparison of the x-coordinate and the y-coordinate of at least the portion of the plurality of vias with the production file for the current layer, the offset data being used to generate alignment data to align the substrate prior to an exposure on a subsequent one of the plurality of layers; and entering the offset data into a lithographic tool database.

In various embodiments, the disclosed subject-matter includes a system to produce an alignment data for a lithographic tool for each of a plurality of layers formed on a substrate that are to underlie a subsequently formed layer. The system includes one or more processors configured to compare measurements of x-coordinates and y-coordinates received from a measurement tool of at least the portion of the plurality of vias on a layer to respective locations of a production file used to determine a planned location of the plurality of vias on a current layer; prepare offset data based on the comparison of the x-coordinates and the y-coordinates of at least the portion of the plurality of vias with the production file for the current layer; and enter the offset data into a lithographic tool database.

In various embodiments, the disclosed subject-matter includes a computer-readable medium containing instructions that, when executed by a machine, cause the machine to perform operations for producing alignment data for a lithographic tool for each of a plurality of layers formed on a substrate that are to underlie a subsequently formed layer. The operations include receiving measurement data for a substrate for each of a plurality of vias within a layer as the plurality of layers are being formed on a substrate, the measurement data including at least an x-coordinate and a y-coordinate of at least a portion of the plurality of vias on each of the plurality of layers; comparing the x-coordinate and the y-coordinate of at least the portion of the plurality of vias on a current layer of the plurality layers to respective locations of a production file used to determine a planned location of the plurality of vias on the current layer; for respective layers, preparing data based on the comparison of the x-coordinate and the y-coordinate of at least the portion of the plurality of vias with the production file for the current layer, the data being used to generate alignment data to align the substrate prior to an exposure on a subsequent one of the plurality of layers; and entering the data into a lithographic tool database.

### BRIEF DESCRIPTION OF FIGURES

Various ones of the appended drawings merely illustrate example implementations of the present disclosure and should not be considered as limiting its scope.

FIG. 1 shows a cross-sectional view of a portion of an integrated-circuit device structure having features that are aligned with each other;

FIG. 2A shows a cross-sectional view of a portion of an integrated-circuit device structure having progressively misaligned features per layer, indicating an accumulation of misalignment in the structure;

FIG. 2B shows a plan view of the portion of the integrated-circuit device structure of FIG. 2A having progressively misaligned features, layer-to-layer, as indicated by the cross-sectional view of FIG. 2A;

FIG. 3 shows an example of a method flow incorporated into a fabrication environment to determine a location of vias or features and produce an alignment solution, in accordance with various embodiments of the disclosed subject-matter;

FIG. 4A shows an example of a via misalignment map indicating via x-location and y-location of a number of vias on a portion of a layer in a substrate, in accordance with various embodiments of the disclosed subject-matter;

FIG. 4B shows an example of a via misalignment map indicating via critical dimensions, depths of vias, and x-location and y-location, in accordance with various embodiments of the disclosed subject-matter;

FIG. 4C shows an example of a via histogram indicating via misalignment in an x-direction, dX, as a function of a via CD in a layer of a substrate, in accordance with various embodiments of the disclosed subject-matter;

FIG. 4D shows an example of a lithographic-equipment alignment-solution-offset map, based on input from the data of FIG. 4A through FIG. 4C, in accordance with various embodiments of the disclosed subject-matter;

FIG. 5 is an exemplary flowchart of a method for producing an alignment solution for a lithographic tool (e.g., a stepper), in accordance with various embodiments; and

FIG. 6 shows a block diagram of an example comprising a machine upon which any one or more of the techniques (e.g., methodologies, calculations, etc.) discussed herein may be performed.

### DETAILED DESCRIPTION

When manufacturing advanced packaging substrates, the actual locations of the laser-drilled holes or other structures in a substrate (which can be a wafer or panel) are unknown. This is because there can be errors between where a via hole should be and where it actually is located. In order to have good alignment between each layer of the substrate it is advantageous to measure the actual locations of via holes and other structures before performing other steps, such as lithography. The measurements can be used to create offset measurements that can be fed forward to processing equipment so that the alignment is better and the yield is higher. The processing equipment can include lithographic equipment.

Various types of lithographic equipment may use an alignment microscope for each of a number of subpanels located on a substrate. In one example, a particular piece of lithographic equipment may use four alignment microscopes to align each of four subpanels. In a typical process, the lithographic equipment provides alignment data from only four points per subpanel to create a final version of an alignment solution.

Various examples disclosed herein describe an apparatus and related method to track and correct alignment errors of vias or other structures used to form an advanced packaging substrate. For example, in various embodiments, the disclosed subject-matter includes a method for measuring locations (e.g., x-coordinate and y-coordinate) of a number of vias or other structures on a layer on the substrate; compare the locations (e.g., x-coordinate and the y-coordinate) on the layer to respective locations of a production file used to determine a planned location of the vias; prepare offset data based on the comparison; and enter the offset data into a lithographic tool database to minimize or correct the alignment errors. Other systems, apparatuses, and methods are also disclosed.

One advantage of this technique solution is the accuracy of the alignment solution and resulting overlay improvement due to the significantly larger dataset used to produce the alignment solution. However, once the alignment solution is produced and entered into the lithographic tool database, only two points (for example, per exposure or direct-write field) can be used for alignment of a substrate (e.g., a panel), thereby increasing throughput of substrates significantly. The two points may, for example, be aligned to opposing diagonal points on the substrate or a variety of other points selected by a user of the methods and systems disclosed herein.

The disclosed subject-matter is therefore directed to an apparatus to align lithography equipment (also referred to in the industry as lithography tools). The lithography equipment can be lithographic equipment (e.g., including photolithographic steppers (steppers) or scanners) used as part of in-line, substrate or panel-production equipment. Exposing generally refers to altering the chemistry of a material on a substrate. The exposing can be accomplished using a light with certain wavelengths or a laser depending on the lithography tool. The substrate can be, for example, an Advanced Integrated Circuit Substrates (AICS) panel or another type of panel or substrate, such as a glass or copper-clad laminate (CCL) panel. The panel may be, for example, a flat-panel display or another substrate type.

As used herein, a person of ordinary skill in the art will recognize that other lithographic tools, such as steppers and direct-write lithography systems, can also benefit from the disclosed subject-matter. Therefore, the term “lithographic tool” may be used herein simply for brevity to cover all types of lithographic exposure and direct-write tools.

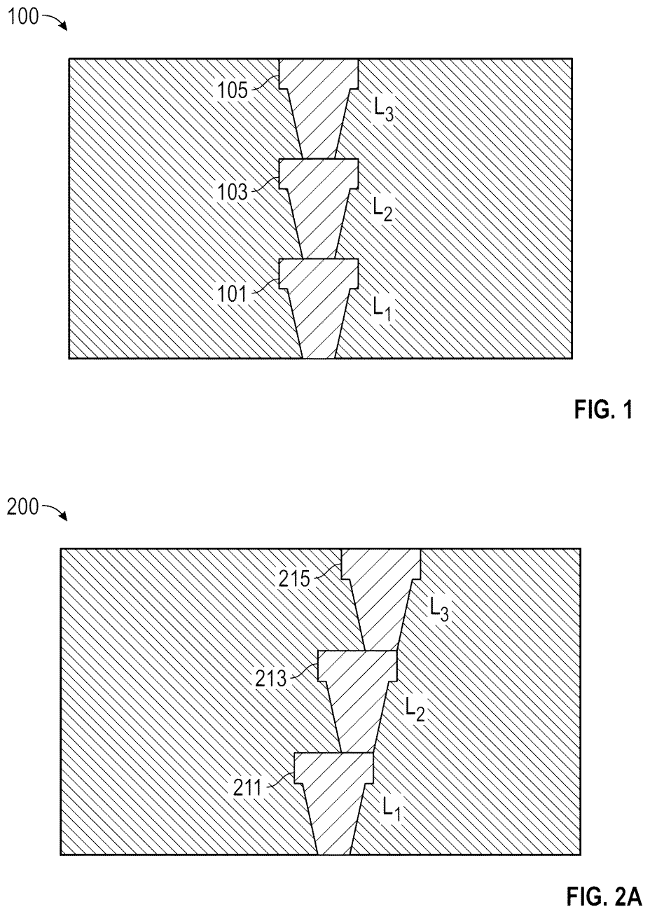

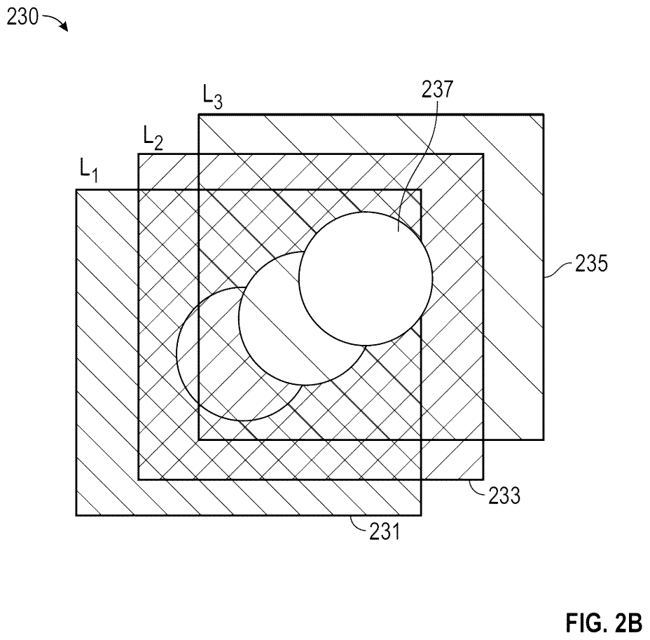

With reference now to FIG. 1, a cross-sectional view of an aligned-version of an overlay structure 100 having features that are aligned with each other, from layer-to-layer (in this example, a first layer, L₁, to a third layer, L₃) is shown. The overlay structure 100 may be a portion of an IC device. Since the features of FIG. 1 are shown from only a two-dimensional perspective, the overlay structure 100 can be considered to be viewed from either front-to-back or side-to-side with reference to a cross-section of the layers (layer L₁ through layer L₃) formed on a substrate. The distinction of FIG. 1 (e.g., with comparison to FIG. 2B, discussed below) is that the features are aligned in both directions (an x-direction and a y-direction). Consequently, the features are aligned in both directions with regard to a plane parallel (an x-y plane) to a surface of the substrate on which the layers are formed.

FIG. 1 is shown to include a first formed-feature 101 within a first layer (L₁). The first formed-feature 101 can be considered to be, for example, either a via or a via that is formed and subsequently filled with a conductive substance, such as tungsten (W), forming a conductive contact-point. A second formed-feature 103 (e.g., a second filled-via) is formed within a second layer (L₂) in vertical alignment with the first formed-feature 101. A third formed-feature 105 (e.g., a third filled-via) is formed within a third layer (L₃) in vertical alignment with both the immediately adjacent second formed-feature 103 and the further underlying first formed-feature 101. Since each of the subsequently formed features is vertically aligned with each of respective ones of the underlying features, an overall level of contact resistance is reduced or minimized between the three layers.

In contrast to the overlay structure 100 of FIG. 1, FIG. 2A shows a cross-sectional view of a portion of an integrated-circuit device structure 200 having progressively misaligned features per layer, indicating an accumulation of misalignment in the structure 200. The accumulated misalignment of features in the structure 200 results in an increased level of contact resistance (e.g., an interconnect resistance), both layer-to-layer as well as from the layers to a substrate (not shown in FIG. 2A), on which the structure 200 is formed, to a top layer (e.g., layer L₈) of the structure 110.

FIG. 2A is shown to include a first formed-feature 211 within a first layer (L₁). The first formed-feature 211 may be similar to or the same as the first formed-feature 101 of FIG. 1 (e.g., a filled via). A second formed-feature 213 (e.g., a second filled-via) is formed within a second layer (L₂), but is positionally misaligned with reference to the first formed-feature 211. A third formed-feature 215 (e.g., a third filled-via) is formed within a third layer (La). The third formed-feature 215 is positionally misaligned with reference to the positions of both the immediately adjacent second formed-feature 213 and the further underlying first formed-feature 211. However, in an example not shown, the third formed-feature 215 may be positionally misaligned with reference to immediately adjacent second formed-feature 213 but positionally aligned with reference to the first formed-feature 211 or further misaligned in a different direction (e.g., to the left) of the first formed-feature 211.

The positional misalignment of each of the subsequently formed features (e.g., the second formed-feature 213 and the third formed-feature 215), both a layer-to-layer contact resistance and an overall level of contact resistance is increased. The overall level of contact resistance is continually increasing due to the misalignment of each feature within the subsequently formed layers with regard to the adjacent feature in the previously formed layer. At least a portion of the increased contact resistance may be a result of, for example, the reduced contact area of subsequently formed features. Although the shift of the features is shown in a single direction (lower-left to upper-right), the shift can occur in any direction or in multiple directions.

FIG. 2B shows a plan view 230 of the portion of the integrated-circuit device structure of FIG. 2A having progressively misaligned features, layer-to-layer, as indicated by the cross-sectional view of FIG. 2A. FIG. 2B is shown to include a portion of a first layer (L₁) 231, a portion of a second layer (L₂) 233, and a portion of a third layer (La) 235. The third layer 235 shows a feature 237 formed within the third layer 235. The feature 237 may be considered to be a plan view of the third formed-feature 215 of FIG. 2A. Each of the underlying layers, the first layer 231 and the second layer 233, also have features formed respectively therein (e.g., such as the first formed-feature 211 and the second formed-feature 213 of FIG. 2A). The formed-features can also be pads, alignment marks, lines (such as signal or power), passive devices (e.g., capacitors, inductors), active devices (circuits), and/or traces.

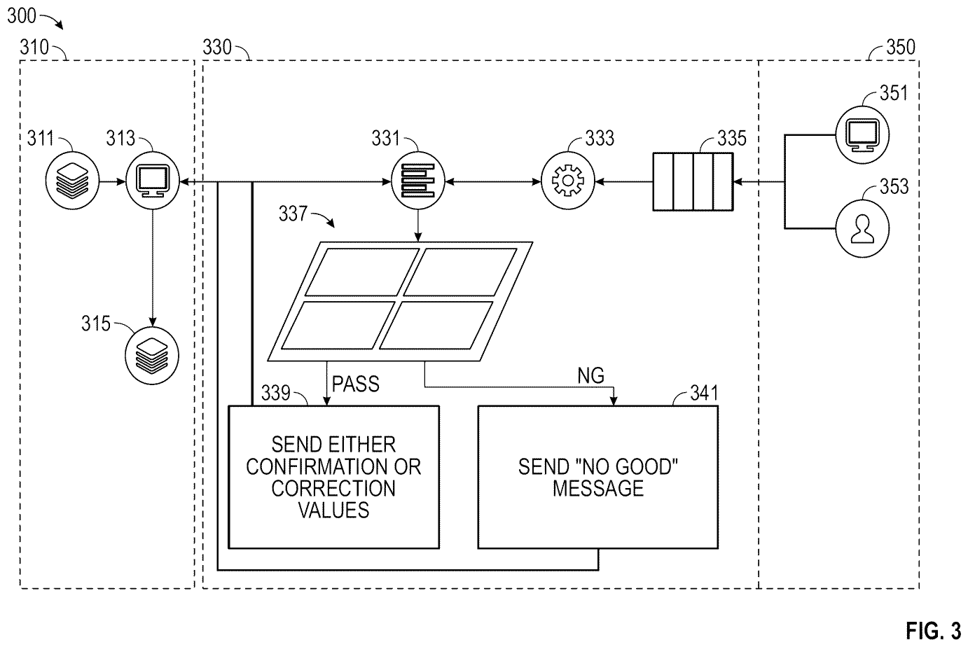

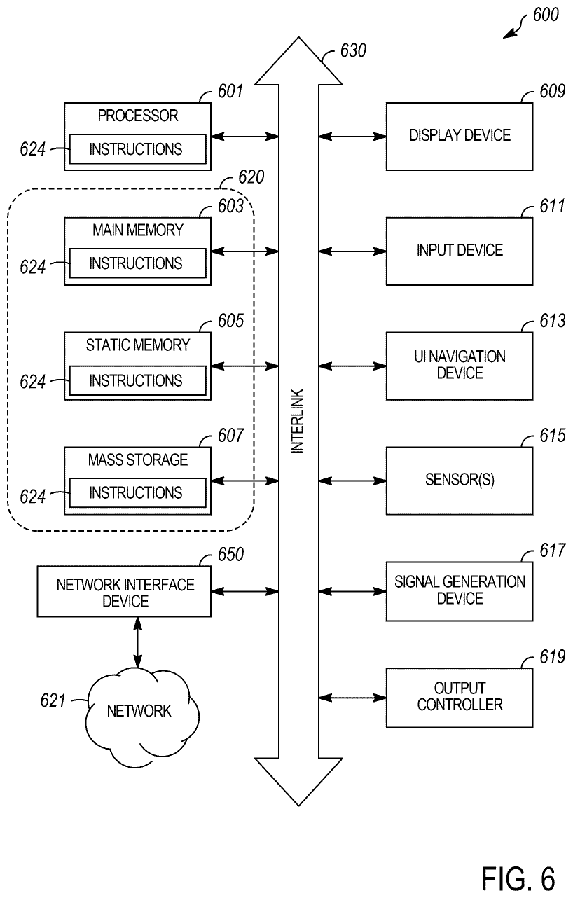

FIG. 3 shows an example of a method incorporated into a fabrication environment 300 to determine a location of vias or other features and produce an alignment solution, in accordance with various embodiments of the disclosed subject-matter. FIG. 3 is shown to include a lithographic module 310, a measurement-analysis module 330, and a CD and position measurement module and input module 350 (measurement and input module 350). The measurement and input module 350 is shown to include at least one measurement tool 351 (which can be an optical-measurement tool, a laser-based measurement tool, an x-ray measurement tool, or any other type of measuring tool) and a user-input overlay-results module 353. In various embodiments, at least certain ones of the lithographic module 310, the measurement-analysis module 330, and the measurement and input module 350 may all communicate with each other over one or more networks as described, for example, with reference to FIG. 6, below.

The lithographic module 310 is shown to include a substrate-input database 311, a lithographic exposure tool 313 (which can be a lithographic stepper), and a substrate-output database 315. The substrate-input database 311 may include one or more memory devices (e.g., solid-state memory, a hard drive, random-access memory (RAM), or any other type of volatile or non-volatile memory known in the art, for example, as described in more detail below, with reference to FIG. 6). The substrate-input database 311 can be used to store patterns and various coordinates (e.g., x- and y-coordinates and CD measurements with reference to a known location) where exposures are to be performed or scanned across a substrate by the lithographic exposure tool 313. The substrate-input database 311 can be used to store the various coordinate locations on the substrate to drive the lithographic exposure tool 313. Additionally, the substrate-input database 311 may be used to store at least a portion of other process recipes used to fabricate devices on the substrate.

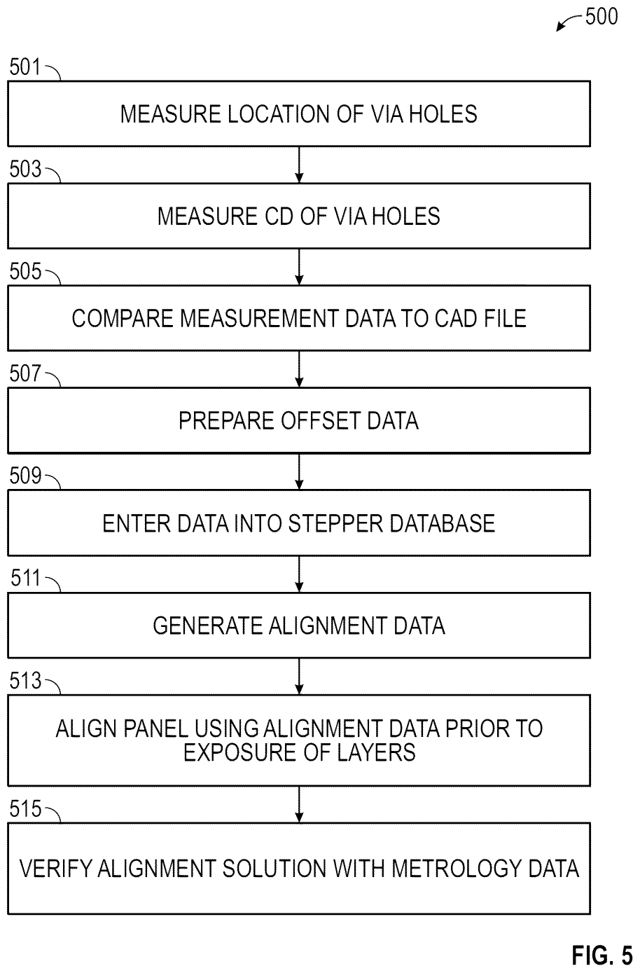

As noted above, the lithographic exposure tool 313 can include various types of, for example, projection-exposure systems, such as steppers and scanners. The substrate-output database 315 may include one or more memory devices (e.g., solid-state memory, a hard drive, random-access memory (RAM), or any other type of volatile or non-volatile memory known in the art) that are the same as or similar to the substrate-input database 311. The substrate-output database 315 may be used to store, for example, various coordinate offsets as received from other components within the fabrication environment 300 received from the measurement-analysis module 330 and the measurement and input module 350 as described in more detail with reference to FIG. 5, below. In various embodiments, the substrate-input database 311 and the substrate-output database 315 may be different portions of a common database.

The measurement-analysis module 330 includes a first calculation-module 333, a second calculation-module 331, and an alignment-offset database 335. The alignment-offset database 335 can receive measurement data and/or other input data from, for example, the lithographic exposure tool 313 (e.g., if the lithographic exposure tool 313 is equipped with one or more alignment microscopes-such data may be received directly or passed through the first calculation-module 333 and the second calculation-module 331) and the CD-measurement and input module 350.

The first calculation-module 333 receives raw overlay-data from both the lithographic exposure tool 313 and the second calculation-module 331. The first calculation-module 333 also supplies data to the second calculation-module 331. In some embodiments, the first calculation-module 333 receives the raw alignment-data and converts it as needed in a form that is readable by other components within the fabrication environment 300, such as by the lithographic exposure tool 313. Although shown as two separate modules, the first calculation-module 333 and the second calculation-module 331 may be portions of the same module.

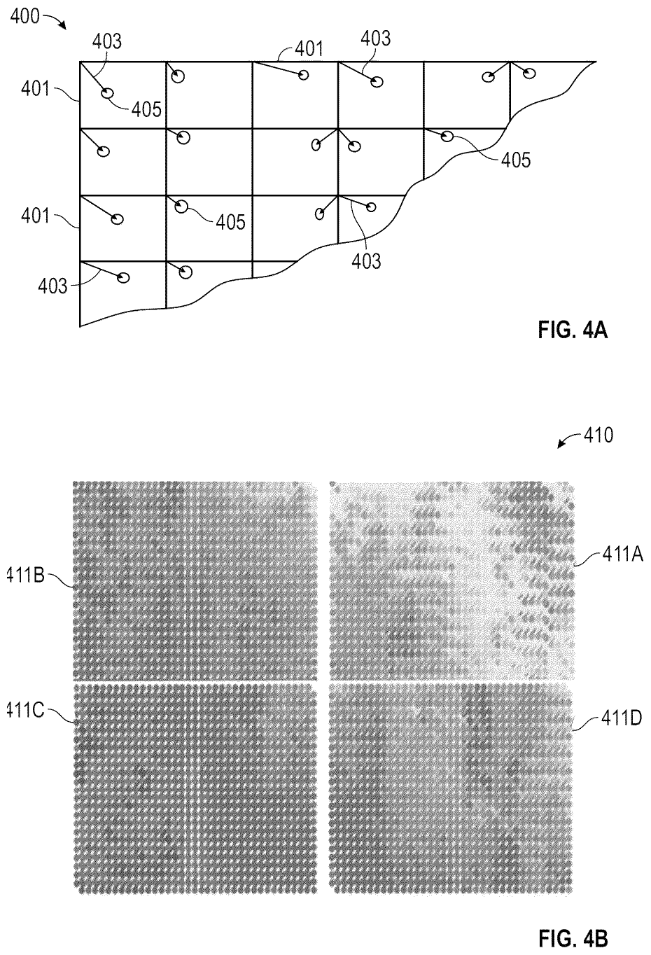

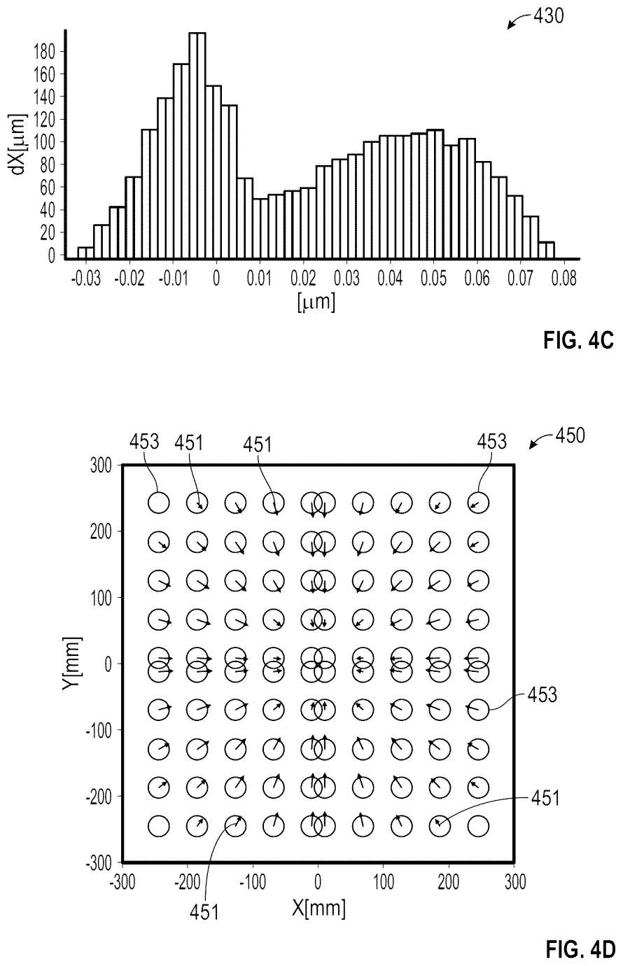

The second calculation-module 331 calculates any offsets that may be desired for the lithographic exposure tool 313 and creates a correction file, which may be stored in, for example, the substrate-output database 315 or another memory/storage location. The lithographic exposure tool 313 may later apply the stored corrections if or when needed. In some embodiments, the second calculation-module 331 may also calculate an accumulation or total-alignment error (or alignment error per subpanel) as described with reference to FIG. 4B and FIG. 5, below. The accumulation or total-alignment error may then be communicated to a host computer (not shown) if the value of the error exceeds a pre-defined threshold value. Consequently, the first calculation-module 333 and the second calculation-module 331 calculate and supply data to the lithographic exposure tool 313, as described in more detail with reference to FIG. 5, below.

An output 337 from the second calculation-module 331 is shown graphically to, for example, feed correction values (e.g., offsets to alignment data) back to the second calculation module 331 and/or the lithographic exposure tool 313 at a “pass” operation 339. Based on a determination that values from the output 337 are outside of the pre-determined tolerance level threshold of a misalignment value, or a cumulative value of misalignment, a signal is sent at a “no good” (NG) operation 341 to the second calculation-module 331 and/or the lithographic exposure tool 313. An operator (e.g., a process or line engineer) may then make a determination whether to rework a substrate undergoing fabrication at that point or simply scrap the substrate.

Further, upon reading and understanding the disclosed subject-matter, a person of ordinary skill in the art will recognize that the first calculation-module 333, the second calculation-module 331, and the alignment-offset database 335 may comprise a single memory, comprising the database, and one or more hardware-based processors to perform calculations. The calculations may include, for example, a determination of accumulated-alignment errors, comparisons of individual alignment errors with a pre-determined tolerance level threshold of a misalignment, and possible corrections for the lithographic exposure tool 313. Consequently, the various components shown in the measurement-analysis module 330 may be grouped together into a single component or may comprise individual components.

As noted above, the CD-measurement module and input module 350 is shown to include at least one measurement tool 351 (which can be an optical-measurement tool, a laser-based measurement tool, an x-ray measurement tool, or any other type of measuring tool) and a user-input overlay-results module 353. The measurement tool 351 may comprise one or more of various types of CD-measurement tools known in the art such as optical and mechanical profilometers, optical and electron microscopes, angle-resolved light scattering and scatterometry tools, or various other types of other manual inspection and automated-inspection tools known in the art. The CD measurements may be performed manually or automatically by the measurement tool 351. The user-input overlay-results module 353 provides an input to the CD-measurement and input module 350 where offline measurements may be input, for example, manually or automatically from another location or tool, to the fabrication environment 300. Original production files (e.g., CAD data) may also be contained with the user-input overlay-results module 353.

FIG. 4A shows an example of a via misalignment map 400 indicating via x-location and y-location of a number of vias 405 on a portion of a layer in a substrate, in accordance with various embodiments of the disclosed subject-matter. Each one of the vias 405 may be considered to be within an arbitrary boundary 401 (shown as a rectangle in FIG. 4A). A vector 403 may then be determined from a known location on the arbitrary boundary 401 (e.g., such as from a top left-hand corner) to an approximate center location of each of the vias 405. An alignment offset based on each vector 403, associated with an actual location of each of the vias 405, to a planned location of respective ones of the vias 405 (e.g., as determined from a production file or CAD file, as described in more detail with reference to fog 5, below) is used to determine a magnitude of alignment offset. In various embodiments, each of the actual locations of the vias 405 is compared with a planned location of respective vias is used in making a further determination for data to be input into an alignment database. In other embodiments, a subset of each of the actual locations of the vias 405 is compared with a planned location of the respective vias is used in making a further determination for data to be input into an alignment database. Such a determination as to how many of the vias 405 to include in making a further determination for data to be input into an alignment database may be based on, for example, a complexity level or design rule used for forming a given feature (e.g., an integrated circuit) on the substrate, as discussed in more detail below.

FIG. 4B shows an example of a via misalignment map 410 indicating via critical dimensions, depths of vias, and x-location and y-location, in accordance with various embodiments of the disclosed subject-matter. The example of the misalignment map 410 is shown to include four subpanels, 411A, 411B, 411C, and 411D. However, fewer than four or more than four subpanels may be used in producing the via misalignment map 410.

In various embodiments, a location and CD of, for example, laser-drilled ABF vias is initially unknown and may be dependent upon factors such as the x- and y-stage accuracy and precision and/or beam calibration of a laser-drilling tool. As describe in more detail with reference to FIG. 3 and FIG. 5 herein, registration errors (including the x- and y-stage and the beam calibration-induced errors) can impact a determination of a via overlay. These data are then used with other data collected as described herein to produce alignment data as described below with reference to FIG. 5.

FIG. 4C shows an example of a via histogram 430 indicating via misalignment in an x-direction, dX, as a function of a via CD in a layer of a substrate, in accordance with various embodiments of the disclosed subject-matter. The via histogram 430 may be used to produce an alignment offset for the lithographic tool for a given region exposed or written onto a substrate. Depending on, for example, a distance between vias and/or an areal size of an exposure/write field, the via histogram 430 may be used to offset each via or a group of vias within the areal size of the exposure/write field. If used for a group of vias, a statistical value, such as at least one or a mean offset or a median offset value, as determined from the entirety of or a portion of the data within the via histogram 430, may be calculated and used for the entire field. Histograms for other misalignment values, such as in a y-direction, may be produced in a similar fashion as the via histogram 430.

FIG. 4D shows an example of a lithographic-equipment alignment-solution-offset map 450, based on input from the data of FIG. 4A through FIG. 4C, in accordance with various embodiments of the disclosed subject-matter. The example of the lithographic-equipment alignment-solution-offset map 450 is shown to include an offset vector 451 for each of a number of vias 453 (or areal exposure/write fields depending on a particular application). In this example, the lithographic-equipment alignment-solution-offset map 450 is shown produced for a subs (or panel) size of 600 mm by 600 mm. The use of such data is described below with reference to FIG. 5.

FIG. 5 is an exemplary flowchart 500 of a method for producing an alignment solution for a processing tool (e.g., a lithographic tool such as a stepper), in accordance with various embodiments. The exemplary flowchart 500 may be applied to each layer in, for example, a substrate such as an Advanced Integrated-Circuit Substrate (AICS). An AICS often uses via holes (vias) formed through an interconnect placed between redistribution layers (RDLs). An AICS package may contain twenty of more process layers (10 layers on each side of the AICS package). One interconnect type frequently used is an Ajinomoto Build-up Film (ABF)) formed between RDLs. The vias are frequently formed through the ABF using laser-drilling techniques.

However, thermal cycling of the substrate and the variously s formed thereon during production of the AICS, together with an increasing number of RDLs, can distort the underlying substrate, frequently in a non-linear fashion. This non-linear distortion results in each portion (e.g., an exposure field) of the panel having vastly different overlay results when a global-alignment solution is applied, as is currently done. Cumulative overlay drift from individual layers can significantly increase overall trace lengths, resulting in higher interconnect resistance, parasitic effects, and a resultant poor performance for high-speed and high-frequency devices formed on an AICS.

Consequently, due at least to the aforementioned non-linear distortions, absolute locations of the laser drilled holes is unknown. In a typical operation, a lithographic tool may use optical microscopes contained therein to align each subpanel, per layer, within the AICS to prepare a final-alignment solution to align a subsequent subpanel with an underlying subpanel previously formed (or to algin a first subpanel with positional locations, such as through-substrate vias, on an underlying substrate). Therefore, the final-alignment solution may be based on, for example, only four points (e.g., the outermost corners of the subpanel).

As defined within the exemplary flowchart 500, metrology data are used to determine actual via locations, compare the data to positional locations within a file (e.g., CAD data), and calculate actual CDs, x-locations, and y-locations, and every selected via on the substrate or layer. These raw data (millions of data points), or user defined subset, provides input to, for example, various types of software to provide a final-alignment solution for a lithographic tool. The alignment solution can compute corrections required for each of exposure or direct-write field formed on the substrate or layer for the AICS. The selected vias may be chosen to be all vias or a subset of the vias. The selection of the number of vias to be measured may be made depending on factors such a complexity level of the AICS, the design rules used to produce a layer or layers of the AICS, and other factors. Therefore, multi-layer overlay drift, as described with reference to FIGS. 1, 2A, and 2B above, can be tracked and compensated for without requiring send-ahead substrates.

At operation 501, a measurement of a location of via holes on a substrate is performed. At operation 503, a measurement of the critical dimension (CD) of the via holes is performed. The measurements of the locations of the via holes and the measurements of the CDs may be performed using, for example, the at least one measurement tool 351 of FIG. 3. In various embodiments, at least partially depending on a complexity of features (e.g., an integrated circuit), to be produced on a substrate, a number of sample vias may be selected for measurement of location and/or CD. In other embodiments, each of the vias on the substrate may be selected for measurement of location and/or CD.

At operation 505, the measurement data are compared with a production file, such as a CAD file, that was used to determine a layout of the initial via locations so as to prepare offsets in alignment differences between the original production files and an actual location and CD variation of the actual measurements taken at operations 501, 503. As noted above with reference to FIG. 3, the production file may be stored at, for example, the user-input overlay-results module 353 At operation 507, an offset-data file is prepared from the comparison of the measurement date with the production file performed at operation 505. The offset-data file may be produced from a determination by a comparison of the actual measurement data compared with the production files and calculated by, for example, one or both of the first calculation-module 333 and the second calculation-module 331. The offset-data file may then be stored at, for example, the alignment-offset database 335 of FIG. 3. The offset-data file is loaded into a stepper database at operation 509. The stepper database may be the same as or similar to the substrate-input database 311 of FIG. 3. The offset-data file is used to generate alignment data for the stepper at operation 511.

At operation 513, the alignment data that were generated at operation 511 are used to align a panel (e.g., a substrate upon which features will be formed) prior to exposure or direct-writing of each of the layers on the substrate (e.g., the AICS panel). After the substrate is exposed, a location of all or a portion of the vias may be compared at operation 515 with the original production file to verify the alignment solution generated at operation 511. The locations of all or the portion of the vias may be measured using, for example, the at least one measurement tool 351 of FIG. 3. the exemplary flowchart 500 may then be repeated for each subsequently produced layer.

FIG. 6 shows an exemplary block diagram comprising a machine 600 upon which any one or more of the techniques (e.g., methods, analysis, or methodologies) discussed herein may be performed herein may be performed. In various examples, the machine 600 may operate as a standalone device or may be connected (e.g., networked) to other machines. In a networked deployment, the machine 600 may operate in the capacity of a server machine, a client machine, or both in server-client network environments. In an example, the machine 600 may act as a peer machine in peer-to-peer (P2P) (or other distributed) network environment. The machine 600 may be a personal computer (PC), a tablet device, a set-top box (STB), a personal digital assistant (PDA), a mobile telephone, a web appliance, a network router, switch or bridge, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations.

Examples, as described herein, may include, or may operate by, logic or a number of components, or mechanisms. Circuitry is a collection of circuits implemented in tangible entities that include hardware (e.g., simple circuits, gates, logic, etc.). Circuitry membership may be flexible over time and underlying hardware variability. Circuitries include members that may, alone or in combination, perform specified operations when operating. In an example, hardware of the circuitry may be immutably designed to carry out a specific operation (e.g., hardwired). In an example, the hardware comprising the circuitry may include variably connected physical components (e.g., execution units, transistors, simple circuits, etc.) including a computer-readable medium physically modified (e.g., magnetically, electrically, such as via a change in physical state or transformation of another physical characteristic, etc.) to encode instructions of the specific operation. In connecting the physical components, the underlying electrical properties of a hardware constituent may be changed, for example, from an insulating characteristic to a conductive characteristic or vice versa. The instructions enable embedded hardware (e.g., the execution units or a loading mechanism) to create members of the circuitry in hardware via the variable connections to carry out portions of the specific operation when in operation. Accordingly, the computer-readable medium is communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry at a different time.

The machine 600 (e.g., computer system) may include a hardware processor 601 (e.g., a central processing unit (CPU), a graphics processing unit (GPU), a hardware processor core, or any combination thereof), a main memory 603 and a static memory 605, some or all of which may communicate with each other via an interlink 630 (e.g., a bus). The machine 600 may further include a display device 609, an input device 611 (e.g., an alphanumeric keyboard), and a user interface (UI) navigation device 613 (e.g., a mouse). In an example, the display device 609, the input device 611, and the UI navigation device 613 may comprise at least portions of a touch screen display. The machine 600 may additionally include a storage device 620 (e.g., a drive unit), a signal generation device 617 (e.g., a speaker), a network interface device 650, and one or more sensors 615, such as a global positioning system (GPS) sensor, compass, accelerometer, or other type of sensor. The machine 600 may include an output controller 619, such as a serial controller or interface (e.g., a universal serial bus (USB)), a parallel controller or interface, or other wired or wireless (e.g., infrared (IR) controllers or interfaces, near field communication (NFC), etc., coupled to communicate or control one or more peripheral devices (e.g., a printer, a card reader, etc.).

The storage device 620 may include a machine-readable medium on which is stored one or more sets of data structures or instructions 624 (e.g., software or firmware) embodying or utilized by any one or more of the techniques or functions described herein. The instructions 624 may also reside, completely or at least partially, within a main memory 603, within a static memory 605, within a mass storage device 607, or within the hardware-based processor 601 during execution thereof by the machine 600. In an example, one or any combination of the hardware-based processor 601, the main memory 603, the static memory 605, or the storage device 620 may constitute machine readable media.

While the machine-readable medium is considered as a single medium, the term “machine-readable medium” may include a single medium or multiple media (e.g., a centralized or distributed database, and/or associated caches and servers) configured to store the one or more instructions 624.

The term “machine-readable medium” may include any medium that is capable of storing, encoding, or carrying instructions for execution by the machine 600 and that cause the machine 600 to perform any one or more of the techniques of the present disclosure, or that is capable of storing, encoding or carrying data structures used by or associated with such instructions. Non-limiting machine-readable medium examples may include solid-state memories, and optical and magnetic media. Accordingly, machine-readable media are not transitory propagating signals. Specific examples of massed machine-readable media may include, for example, non-volatile memory, such as semiconductor memory devices (e.g., Electrically Programmable Read-Only Memory (EPROM), Electrically Erasable Programmable Read-Only Memory (EEPROM)) and flash memory devices; magnetic or other phase-change or state-change memory circuits; magnetic disks, such as internal hard disks and removable disks; magneto-optical disks; and CD-ROM and DVD-ROM disks.

The instructions 624 may further be transmitted or received over a communications network 621 using a transmission medium via the network interface device 650 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., the Institute of Electrical and Electronics Engineers (IEEE) 802.22 family of standards known as Wi-Fix, the IEEE 802.26 family of standards known as WiMax®), the IEEE 802.25.4 family of standards, peer-to-peer (P2P) networks, among others. In an example, the network interface device 650 may include one or more physical jacks (e.g., Ethernet, coaxial, or phone jacks) or one or more antennas to connect to the communications network 621. In an example, the network interface device 650 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding or carrying instructions for execution by the machine 600, and includes digital or analog communications signals or other intangible medium to facilitate communication of such software.

As used herein, the term “or” may be construed in an inclusive or exclusive sense. Further, other embodiments will be understood by a person of ordinary skill in the art based upon reading and understanding the disclosure provided. Moreover, the person of ordinary skill in the art will readily understand that various combinations of the techniques and examples provided herein may all be applied in various combinations.

Throughout this specification, plural instances may implement components, operations, or structures described as a single instance. Although individual operations are illustrated and described as separate operations, one or more of the individual operations may be performed concurrently, and, unless otherwise stated, nothing requires that the operations necessarily be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter described herein.

Further, although not shown explicitly but understandable to a skilled artisan, each of the various arrangements, quantities, and number of elements may be varied (e.g., the number layers to be added to a substrate, the number of vias or features per layer that are measured for x-coordinate and y-coordinate locations, the number of comparisons with pre-defined threshold values, etc.). Moreover, each of the examples shown and described herein is merely representative of one possible configuration or method and should not be taken as limiting the scope of the disclosure.

Although various embodiments are discussed separately, these separate embodiments are not intended to be considered as independent techniques or designs. As indicated above, each of the various portions may be inter-related and each may be used separately or in combination with other embodiments discussed herein. For example, although various embodiments of operations, systems, and processes have been described, these methods, operations, systems, and processes may be used either separately or in various combinations.

Consequently, many modifications and variations can be made, as will be apparent to a person of ordinary skill in the art upon reading and understanding the disclosure provided herein. Functionally equivalent methods and devices within the scope of the disclosure, in addition to those enumerated herein, will be apparent to the skilled artisan from the foregoing descriptions. Portions and features of some embodiments may be included in, or substituted for, those of others. Such modifications and variations are intended to fall within a scope of the appended claims. Therefore, the present disclosure is to be limited only by the terms of the appended claims, along with the full scope of equivalents to which such claims are entitled. It is also to be understood that the terminology used herein is for the purpose of describing particular embodiments only and is not intended to be limiting.

The Abstract of the Disclosure is provided to allow the reader to ascertain quickly the nature of the technical disclosure. The abstract is submitted with the understanding that it will not be used to interpret or limit the claims. In addition, in the foregoing Detailed Description, it may be seen that various features may be grouped together in a single embodiment for the purpose of streamlining the disclosure. This method of disclosure is not to be interpreted as limiting the claims. Thus, the following claims are hereby incorporated into the Detailed Description, with each claim standing on its own as a separate embodiment.

The description provided herein includes illustrative examples, devices, and apparatuses that embody various aspects of the matter described in this document. In the description, for purposes of explanation, numerous specific details are set forth in order to provide an understanding of various embodiments of the matter discussed. It will be evident however, to those of ordinary skill in the art, that various embodiments of the disclosed subject-matter may be practiced without these specific details. Further, well-known structures, materials, and techniques have not been shown in detail, so as not to obscure the various illustrated embodiments. As used herein, the terms “about,” “approximately,” and “substantially” may refer to values that are, for example, within ±10% of a given value or range of values.

### THE FOLLOWING NUMBERED EXAMPLES ARE SPECIFIC EMBODIMENTS OF THE DISCLOSED SUBJECT-MATTER

Example 1: An embodiment of the disclosed subject-matter describes a method for producing alignment data for a lithographic tool for each of a plurality of layers formed on a substrate that are to underlie a subsequently formed layer. The method includes receiving measurement data for a substrate for each of a plurality of vias within a layer as the plurality of layers are being formed on a substrate. The measurement data including at least an x-coordinate and a y-coordinate of at least a portion of the plurality of vias on a layer of the substrate. The method also includes comparing the x-coordinate and the y-coordinate of at least the portion of the plurality of vias on a current layer of the substrate to respective locations of a production file used to determine a planned location of the plurality of vias on the current layer; preparing offset data based on the comparison of the x-coordinate and the y-coordinate of at least the portion of the plurality of vias with the production file for the current layer, the offset data being used to generate alignment data to align the substrate prior to an exposure on a subsequent one of the plurality of layers; and entering the offset data into a lithographic tool database.

Example 2: The method of Example 1, wherein the plurality of vias include conductive contact-points of redistribution layers (RDLs).

Example 3: The method of either Example 1 or Example 2, further comprising measuring critical dimensions of at least a portion of the plurality of vias.

Example 4: The method of any one of the preceding Examples, further comprising generating a via histogram from the critical dimension measurements and the x-coordinate and the y-coordinate for each of the layers formed on the substrate that are to underlie the subsequently formed layer.

Example 5: The method of any one of the preceding Examples, further comprising calculating a statistical value of a combination of the x-coordinate and the y-coordinate from the via histogram.

Example 6: The method of Example 5, wherein the statistical value comprises at least one of a mean offset value and a median offset value.

Example 7: The method of any one of the preceding Examples, wherein the measuring of the x-coordinate and the y-coordinate of at least a portion of the plurality of vias is performed automatically.

Example 8: The method of any one of the preceding Examples, further comprising using user-input overlay results in addition to the measuring of the x-coordinate and the y-coordinate of at least a portion of the plurality of vias.

Example 9: The method of any one of the preceding Examples, further comprising, prior to exposing features on a subsequent one of the plurality of layers to be formed on the substrate, aligning the substrate using the offset data from the current layer.

Example 10: The method of any one of the preceding Examples, wherein the received measurement data is produced by using one or more measurement tools.

Example 11: An embodiment of the disclosed subject-matter describes a system to produce an alignment data for a lithographic tool for each of a plurality of layers formed on a substrate that are to underlie a subsequently formed layer. The system includes one or more processors configured to compare measurements of x-coordinates and y-coordinates received from a measurement tool of at least the portion of the plurality of vias on a layer to respective locations of a production file used to determine a planned location of the plurality of vias on a current layer; prepare offset data based on the comparison of the x-coordinates and the y-coordinates of at least the portion of the plurality of vias with the production file for the current layer; and enter the offset data into a lithographic tool database.

Example 12: The system of Example 11, wherein the measurements of the x-coordinates and the y-coordinates of at least the portion of the plurality of vias are to be performed automatically.

Example 13: The system of Example 12, further comprising using user-input overlay results in addition to the measurements of the x-coordinates and the y-coordinates of at least the portion of the vias.

Example 14: The system of Example 13, wherein a measurement tool is configured to measure critical dimensions of at least a portion of the plurality of vias.

Example 15. The system of Example 14, wherein the measurement-analysis module is further configured to generate a via histogram from the critical dimension measurements and the x-coordinates and the y-coordinates for each of the layers formed on a substrate that are to underlie a subsequently formed layer; and calculate a statistical value of a combination of the x-coordinates and the y-coordinates from the via histogram, the statistical value comprising at least one of a mean offset value and a median offset value.

Example 16: The system of any one of Example 11 to Example 15, further comprising a measurement tool configured to, for each of the plurality of layers that are to underlie another layer, measure the x-coordinates and the y-coordinates of at least the portion of the plurality of vias on the layer.

Example 17: An embodiment of the disclosed subject-matter describes a computer-readable medium containing instructions that, when executed by a machine, cause the machine to perform operations for producing alignment data for a lithographic tool for each of a plurality of layers formed on a substrate that are to underlie a subsequently formed layer. The operations include receiving measurement data for a substrate for each of a plurality of vias within a layer as the plurality of layers are being formed on a substrate, the measurement data including at least an x-coordinate and a y-coordinate of at least a portion of the plurality of vias on each of the plurality of layers; comparing the x-coordinate and the y-coordinate of at least the portion of the plurality of vias on a current layer of the plurality layers to respective locations of a production file used to determine a planned location of the plurality of vias on the current layer; for respective layers, preparing data based on the comparison of the x-coordinate and the y-coordinate of at least the portion of the plurality of vias with the production file for the current layer, the data being used to generate alignment data to align the substrate prior to an exposure on a subsequent one of the plurality of layers; and entering the data into a lithographic tool database.

Example 18: The computer-readable medium of Example 17, further comprising measuring critical dimensions of at least a portion of the plurality of vias on each of the plurality of layers.

Example 19: The computer-readable medium of Example 18, further comprising generating a via histogram from the critical dimension measurements and the x-coordinates and the y-coordinates for each of the layers formed on the substrate that are to underlie a subsequently formed layer; and calculating a statistical value of a combination of the x-coordinates and the y-coordinates from the via histogram, the statistical value comprising at least one of a mean offset value and a median offset value.

Example 20: The computer-readable medium of any one of Example 17 to Example 19, further comprising, prior to exposing features on the substrate, aligning the substrate using the data.

Example 21: The computer-readable medium of any one of Example 17 to Example 20, further comprising verifying the alignment data with one or more measurement tools for each of the layers formed on the substrate that are to underlie a subsequently formed layer.

What is claimed:

1. A method for producing alignment data for a lithographic tool for each of a plurality of layers formed on a substrate that are to underlie a subsequently formed layer, the method comprising:
receiving measurement data for a substrate for each of a plurality of vias within a layer as the plurality of layers are being formed on a substrate, the measurement data including at least an x-coordinate and a y-coordinate of at least a portion of the plurality of vias on a layer of the substrate;
comparing the x-coordinate and the y-coordinate of at least the portion of the plurality of vias on a current layer of the substrate to respective locations of a production file used to determine a planned location of the plurality of vias on the current layer;
preparing offset data based on the comparison of the x-coordinate and the y-coordinate of at least the portion of the plurality of vias with the production file for the current layer, the offset data being used to generate alignment data to align the substrate prior to an exposure on a subsequent one of the plurality of layers; and
entering the offset data into a lithographic tool database.

2. The method of claim 1, wherein the plurality of vias include conductive contact-points of redistribution layers (RDLs).

3. The method of claim 1, further comprising measuring critical dimensions of at least a portion of the plurality of vias.

4. The method of claim 3, further comprising generating a via histogram from the critical dimension measurements and the x-coordinate and the y-coordinate for each of the layers formed on the substrate that are to underlie the subsequently formed layer.

5. The method of claim 4, further comprising calculating a statistical value of a combination of the x-coordinate and the y-coordinate from the via histogram.

6. The method of claim 5, wherein the statistical value comprises at least one of a mean offset value and a median offset value.

7. The method of claim 1, wherein the measuring of the x-coordinate and the y-coordinate of at least a portion of the plurality of vias is performed automatically.

8. The method of claim 1, further comprising using user-input overlay results in addition to the measuring of the x-coordinate and the y-coordinate of at least a portion of the plurality of vias.

9. The method of claim 1, further comprising, prior to exposing features on a subsequent one of the plurality of layers to be formed on the substrate, aligning the substrate using the offset data from the current layer.

10. The method of claim 1, wherein the received measurement data is produced by using one or more measurement tools.

11. A system to produce an alignment data for a lithographic tool for each of a plurality of layers formed on a substrate that are to underlie a subsequently formed layer, the system comprising:
one or more processors configured to:
compare measurements of x-coordinates and y-coordinates received from a measurement tool of at least the portion of the plurality of vias on a layer to respective locations of a production file used to determine a planned location of the plurality of vias on a current layer;
prepare offset data based on the comparison of the x-coordinates and the y-coordinates of at least the portion of the plurality of vias with the production file for the current layer; and
enter the offset data into a lithographic tool database.

12. The system of claim 11, wherein the measurements of the x-coordinates and the y-coordinates of at least the portion of the plurality of vias are to be performed automatically.

13. The system of claim 11, further comprising using user-input overlay results in addition to the measurements of the x-coordinates and the y-coordinates of at least the portion of the vias.

14. The system of claim 13, wherein a measurement tool is configured to measure critical dimensions of at least a portion of the plurality of vias.

15. The system of claim 14, wherein the measurement-analysis module is further configured to:
generate a via histogram from the critical dimension measurements and the x-coordinates and the y-coordinates for each of the layers formed on a substrate that are to underlie a subsequently formed layer; and
calculate a statistical value of a combination of the x-coordinates and the y-coordinates from the via histogram, the statistical value comprising at least one of a mean offset value and a median offset value.

16. The system of claim 11, further comprising a measurement tool configured to, for each of the plurality of layers that are to underlie another layer, measure the x-coordinates and the y-coordinates of at least the portion of the plurality of vias on the layer.

17. A computer-readable medium containing instructions that, when executed by a machine, cause the machine to perform operations for producing alignment data for a lithographic tool for each of a plurality of layers formed on a substrate that are to underlie a subsequently formed layer, the operations comprising:
receiving measurement data for a substrate for each of a plurality of vias within a layer as the plurality of layers are being formed on a substrate, the measurement data including at least an x-coordinate and a y-coordinate of at least a portion of the plurality of vias on each of the plurality of layers;
comparing the x-coordinate and the y-coordinate of at least the portion of the plurality of vias on a current layer of the plurality layers to respective locations of a production file used to determine a planned location of the plurality of vias on the current layer;
for respective layers, preparing data based on the comparison of the x-coordinate and the y-coordinate of at least the portion of the plurality of vias with the production file for the current layer, the data being used to generate alignment data to align the substrate prior to an exposure on a subsequent one of the plurality of layers; and
entering the data into a lithographic tool database.

18. The computer-readable medium of claim 17, further comprising measuring critical dimensions of at least a portion of the plurality of vias on each of the plurality of layers.

19. The computer-readable medium of claim 18, further comprising:
generating a via histogram from the critical dimension measurements and the x-coordinates and the y-coordinates for each of the layers formed on the substrate that are to underlie a subsequently formed layer; and
calculating a statistical value of a combination of the x-coordinates and the y-coordinates from the via histogram, the statistical value comprising at least one of a mean offset value and a median offset value.

20. The computer-readable medium of claim 17, further comprising, prior to exposing features on the substrate, aligning the substrate using the data.

21. The computer-readable medium of claim 17, further comprising verifying the alignment data with one or more measurement tools for each of the layers formed on the substrate that are to underlie a subsequently formed layer.
